(19) United States
(12) Patent Application Publication
(10) Pub. No.: US 2026/0266890 A1
(43) Pub. Date: Sep. 10, 2026

(54) VCSEL Test Methods and Systems

(71) Applicant: PicoJool, Inc., Palo Alto, CA (US)

(72) Inventor: Albert T Yuen, Palo Alto, CA (US)

(73) Assignee: PicoJool, Inc., Palo Alto, CA (US)

(21) Appl. No.: 19/661,630

(22) Filed: Apr. 28, 2026

Related U.S. Application Data
(63) Continuation-in-part of application No. 19/392,172, filed on Nov. 18, 2025.
(60) Provisional application No. 63/723,305, filed on Nov. 21, 2024.

(51) Int. Cl. G01R 31/26

(52) U.S. Cl. CPC G01R 31/2635

(57) ABSTRACT

A method tests a semiconductor wafer carrying multiple bottom-emitting vertical-cavity surface-emitting lasers (BE-VCSELs) and a top-emitting VCSEL (TE-VCSEL) serving as a proximity monitor. The wafer is placed on a thermal wafer chuck with the TE-VCSEL's contact pad facing up. At two or more chuck temperatures, a photodetector placed above the TE-VCSEL measures a performance metric — such as output power, an RF s-parameter, or relative intensity noise — to obtain a temperature-based result. Individual BE-VCSELs may undergo forward and/or reverse bias tests. Based on these results, the BE-VCSELs are accepted or rejected. The semiconductor wafer also has the BE-VCSELs and the TE-VCSEL formed from the same continuous epitaxial layers, and the BE-VCSELs have separate contact pads for probe testing and for active use, each less than 35 microns across.

### PATENT APPLICATION

This application is a continuation-in-part of U.S. patent application serial no. 19/392,172, entitled "Vertical-Cavity Surface-Emitting Laser with Reduced Bondpad Parasitic Capacitances", filed on November 18, 2025, which claims priority from U.S. provisional patent application serial no. 63/723,305, entitled "Bottom-Emitting VCSEL with Tiny Probe Pad and Tiny Flip Chip Bump", filed on November 21, 2024. The priority applications are hereby incorporated by reference, as if they are set forth in full in this specification.

Each publication, patent, and/or patent application mentioned in this specification is herein incorporated by reference in its entirety to the same extent as if each individual publication and/or patent application was specifically and individually indicated to be incorporated by reference.

### BACKGROUND

### TECHNICAL FIELD

The disclosed implementations relate generally to systems and methods used in photonics, optical communication, and LiDAR, and in particular to those for the testing, design, and production of vertical-cavity surface-emitting lasers (VCSELs).

### CONTEXT

VCSELs are a category of semiconductor laser devices in which laser emission occurs in a direction perpendicular to the planar top surface of the wafers on which the semiconductor chips are fabricated.

### BRIEF DESCRIPTION OF THE DRAWINGS

The technology will be described with reference to the drawings, in which:

FIG. 1 illustrates an example method 100 of testing a semiconductor wafer with multiple bottom-emitting vertical-cavity surface-emitting lasers (BE-VCSELs) and a proximity monitor top-emitting vertical-cavity surface-emitting laser (TE-VCSEL).

FIG. 2 shows an example of a wafer prober 200 with a wafer chuck 210 on which a semiconductor wafer 220 is tested. One example test is a reverse bias test 260 on a BE-VCSEL 262.

FIG. 3 illustrates an example of another possible test, a forward bias test 360 on a BE-VCSEL 362.

FIG. 4 shows a side view of part of an example semiconductor wafer 400 with a BE-VCSEL 410 that uses much smaller contact pads than conventional VCSELs, allowing higher speed electric signals to reach BE-VCSEL 410. Contact pad 462 is used during operation in a flip-chip assembly. Optional contact pad 464 may be used during wafer probing for reverse bias and/or forward bias testing. The total area of contact pad 462 and contact pad 464 is smaller than the area of a conventional combined bondpad, thus allowing higher speed operation.

FIG. 5 shows a top view of the part of the semiconductor wafer 400.

FIG. 6 illustrates a sectional view of a part of an example semiconductor wafer 400 with an arrangement of BE-VCSELs and a TE-VCSEL used as a proximity monitor. In this case, semiconductor wafer 400 includes a row 610 of BE-VCSELs, at the end of which is a TE-VCSEL 620.

FIG. 7 illustrates a top view of the part of the semiconductor wafer 400 shown in FIG. 6.

FIG. 8 illustrates a top view of an arrangement of BE-VCSELs in a two-dimensional array 810. In this case, the array has two rows of BE-VCSELs, sharing one TE-VCSEL 620. Larger arrangements may share multiple TE-VCSELs 620 for proximity monitoring.

FIG. 9 illustrates a top view of an example octagonal arrangement of BE-VCSELs 910. The occupied area is small enough that only one TE-VCSEL 620 is needed. Larger arrangements may share multiple TE-VCSELs 620 for proximity monitoring.

FIG. 10 illustrates an example semiconductor wafer 400 in which TE-VCSEL 620 is located within ten millimeters from a first part 1010 of multiple BE-VCSELs and a second TE-VCSEL 621 is located within ten millimeters from a second part 1011 of the multiple BE-VCSELs. Having two (or more) TE-VCSELs serving as proximity monitors makes it possible to perform spatial interpolation in estimating power levels of the BE-VCSELs, increasing estimation accuracy, potentially even beyond ten millimeters.

FIG. 11 illustrates a part of an example multi-chip module (MCM 1100) configured for in-the-field performance monitoring.

In the figures, like reference numbers may indicate functionally similar elements. The systems and methods illustrated in the figures—and described in the Detailed Description below—may be arranged and designed in a wide variety of different implementations. Neither the figures nor the Detailed Description are intended to limit the scope as claimed. Instead, they merely represent examples of different implementations.

### DETAILED DESCRIPTION

Vertical-cavity surface-emitting lasers (VCSELs) are a category of semiconductor laser devices in which laser emission occurs in a direction perpendicular to the planar top surface of the wafers on which the semiconductor chips are fabricated. This geometry allows for more convenient testing (relative to what is possible with edge-emitting lasers) during device fabrication, since VCSEL chips can be tested while they're still part of the wafer, allowing problems to be identified at an early stage when it may still be possible to resolve them, whereas edge-emitting laser chips need to be cut from the wafer before they can be tested. Additionally, VCSELs can be produced in 2-D arrays, which allows for many applications not achievable with edge-emitting lasers.

VCSELs are usually made in a gallium arsenide (GaAs) semiconductor process. They include an active region of a few microns thick, sandwiched between two semiconductor Bragg mirrors, made of layers of epitaxial aluminum gallium arsenide (AlGaAs). The structure sits on a semiconductor substrate (the GaAs wafer). The upper and lower mirrors include doped P-type and N-type materials and form a diode junction at the active region. When the diode carries a current, the active region emits photons. Photons of the laser's wavelength are reflected and amplified by the two mirrors. The mirrors have high, but unequal reflectivity, and eventually the amplified photons leave through the mirror with the lower reflectivity.

To enable communication, light may be modulated at the source (in this case the VCSEL) or later. In that case, the source may generate a steady stream of light, and some external modulator varies the amplitude of the light at a later stage. For various reasons it is attractive to modulate at the source, so the speed of VCSELs has been a longtime subject of research. Electrical, thermal, and optical issues have been found to limit the bandwidth. Over the years, many ways have been published to increase the bandwidth, usually focusing on physical effects inside the VCSEL.

Bottom-emitting VCSELs (BE-VCSELs) are a category of VCSELs designed such that the generated optical signals are directed to pass through the chip's body before emerging from the device. The top surface of such chips may include metallic bonding pads and optional "bumps", allowing the chip to be mounted upside down in a "flip-chip" process. Flip-chip mounting has the advantage that shorter electrical traces can be used with less inductance, resulting in higher signal speeds than can be obtained with traditional bond wire connections. A flip-chip can be mounted directly onto another chip that includes the electronics that steers the BE-VCSEL. In some cases, the flip-chip can be "thinned" after mounting. Thinning is the process of removing part of the semiconductor substrate to reduce optical losses for the optical signal while it travels from the top of the chip where it is generated to the bottom of the chip where it is emitted. Some flip-chip bumps serve as electrical contacts for the signal steering the laser. Other bumps may serve to mechanically stabilize the VCSEL chip and have no electrical function.

In currently available devices, the bumps or contact pads that are used for flip-chip bonding are also used to enable testing of the chips during the earlier wafer probe stage. If the devices are intended for eventual high-speed operation, there are two competing requirements for the bumps. One is to keep their dimensions small enough to minimize parasitic capacitance which can otherwise significantly limit the devices' frequency response. The other is to make the bumps or contact pads sturdy enough, which in practice means large enough, to withstand the wear and tear caused by making and breaking contact with the test probes used in wafer-scale test processes. This results in compromised products, where device performance (speed) is sacrificed for reliability.

As also described in co-pending U.S. patent application 19/392,172 (Vertical-Cavity Surface-Emitting Laser with Reduced Bondpad Parasitic Capacitances) by the same applicant, separate contact pads can be created for probing and for use in final production. By using smaller bumps and contact pads, parasitic capacitances can be minimized so that significantly higher speeds are obtained without loss of reliability.

However, another challenge occurs during wafer testing. A wafer prober includes a wafer chuck, a (usually metal) plate that holds the semiconductor wafer in place during testing. The wafer is placed on the wafer chuck with its contact pads facing up. This means that the BE-VCSELs send their output beams towards the wafer chuck. To measure the power of the output beams and/or other performance metrics, the chuck would need to be transparent or would need to have tiny holes that are exactly lining up with the VCSELs. Below the holes, or the transparent chuck, would need to be photodetectors, again exactly lined up. It may be required to measure performance metrics of the BE-VCSELs at various temperatures, for example at the minimum and the maximum guaranteed operating temperatures for the chips on the semiconductor wafer. Thermal chucks are temperature controlled, and are made from a thermally conductive material, such as aluminum. The thermally conductive material, as well as the heating and/or cooling device, make it practically impossible to measure the performance of the BE-VCSELs this way.

The technology disclosed in this document solves both problems at once. A group of neighboring BE-VCSELs is paired with a top-emitting VCSEL (TE-VCSEL) that is used as a proximity monitor. Although the TE-VCSEL may have different performance characteristics than the BE-VCSELs, their performance metrics are strongly correlated. Therefore, measurements from the TE-VCSEL can serve as a proxy for the performance of the neighboring BE-VCSELs. Performance metrics that can be measured this way include output power, radio-frequency (RF) s-parameters, and relative intensity noise (RIN). The photodetector used for measuring the TE-VCSEL can be further removed from the chuck, and therefore less impacted by the chuck's temperature.

In some cases, both the TE-VCSEL and the BE-VCSELs will be used at the probe stage and in the field. For example, the TE-VCSEL may be used in the field for active power monitoring. If, due to varying operating conditions or aging the VCSELs' output power changes, then active power monitoring will allow to compensate for this and keep the BE-VCSELs' output power at sufficient and safe levels. The BE-VCSELs may still be probed during the test stage, because the TE-VCSEL only gives information about the expected performance level, but not whether each individual BE-VCSEL is operational. That can be determined by reverse bias and forward bias testing of the BE_VCSELs. The high bandwidth can be retained by separating into small contact pads and probe pads as described in U.S. patent application 19/392,172. However, if it is determined that the forward and reverse bias tests are not required during the probe stage, the BE-VCSEL contact pads can be small and the probe pads can be left out altogether. In both cases, BE_VCSEL contact pads can be smaller than the conventional minimum of 50 microns, for example smaller than 35 microns, or even as small as 20 or 10 microns, measured across, so that the highest bandwidth can be obtained.

Conventional wafer test approaches fall into: Category A – direct optical measurement (requires transparent or perforated chuck – impractical for thermal testing); Category B – post-singulation testing (not possible at wafer stage); Category C – electrical-only testing (reverse/forward bias – does not capture optical performance metrics). No approach achieves temperature- dependent optical characterization of BE-VCSELs during wafer probing. The technology disclosed herein falls outside all three categories. Conventional approaches ask: Can we access the optical output of the BE-VCSEL during wafer testing? The present invention asks: Can we correlate the accessible output of a proximate TE-VCSEL to the BE-VCSEL performance without any direct optical access?

### TERMINOLOGY

As used herein, the phrase "one of" should be interpreted to mean exactly one of the listed items. For example, the phrase "one of A, B, and C" should be interpreted to mean any of: only A, only B, or only C.

As used herein, the phrases "at least one of" and "one or more of" should be interpreted to mean one or more items. For example, the phrase "at least one of A, B, or C" or the phrase "one or more of A, B, or C" should be interpreted to mean any combination of A, B, and/or C. The phrase "at least one of A, B, and C" means at least one of A and at least one of B and at least one of C.

Unless otherwise specified, the use of ordinal adjectives first, second, third, etc., to describe an object, merely refers to different instances or classes of the object and does not imply any ranking or sequence.

The terms "comprising" and "consisting" have different meanings in this patent document. An apparatus, method, or product "comprising" (or "including") certain features means that it includes those features but does not exclude the presence of other features. On the other hand, if the apparatus, method, or product "consists of" (or "contains") certain features, the presence of any additional features is excluded.

The term "coupled" is used in an operational sense and is not limited to a direct or an indirect coupling. "Coupled to" is generally used in the sense of directly coupled, whereas "coupled with" is generally used in the sense of directly or indirectly coupled. Coupled in an electronic system may refer to a configuration that allows a flow of information, signals, data, or physical quantities such as electrons between two elements coupled to or coupled with each other. In some cases, the flow may be unidirectional, in other cases the flow may be bidirectional or multidirectional. Coupling may be galvanic (in this context meaning that a direct electrical connection exists), capacitive, inductive, electromagnetic, optical, or through any other process allowed by physics.

The term "connected" is used to indicate a direct connection, such as electrical, optical, electromagnetic, or mechanical, between the things that are connected, without any intervening things or devices.

The terms "interconnect" and "interconnection" are used to indicate (an) electrical coupling or (a) photonic coupling, which may be direct or indirect.

The term "configured" to perform a task or tasks is a broad recitation of structure generally meaning having circuitry that performs the task or tasks during operation. As such, the described item can be configured to perform the task even when the unit/circuit/component is not currently on or active. In general, the circuitry that forms the structure corresponding to configured to may include hardware circuits, and may further be controlled by switches, fuses, bond wires, metal masks, firmware, and/or software. Similarly, various items may be described as performing a task or tasks, for convenience in the description. Such descriptions should be interpreted as including the phrase configured to.

As used herein, the term "based on" is used to describe one or more factors that affect a determination. This term does not foreclose the possibility that additional factors may affect the determination. That is, a determination may be solely based on specified factors or based on the specified factors as well as other, unspecified factors. Consider the phrase "determine A based on B". This phrase specifies that B is a factor that is used to determine A or that affects the determination of A. This phrase does not foreclose that the determination of A may also be based on some other factor, such as C. This phrase is also intended to cover an implementation in which A is determined based solely on B. The phrase based on is thus synonymous with the phrase based at least in part on.

The terms "substantially", "close", "approximately", "near", and "about" refer to being within minus or plus 20% of an indicated value, unless explicitly specified otherwise.

The following terms or acronyms used herein are defined at least in part as follows:

"AlGaAs" – aluminum gallium arsenide – a ternary compound semiconductor composed of aluminum, gallium, and arsenic. AlGaAs is used for the alternating semiconductor layers in distributed Bragg reflectors (DBRs) of VCSELs because its refractive index can be tuned by varying the aluminum fraction. AlGaAs is nearly lattice-matched to GaAs, enabling high-quality epitaxial growth.

"BE-VCSEL" – bottom-emitting vertical-cavity surface-emitting laser – a VCSEL in which the laser beam exits through the bottom mirror and through the substrate, away from the patterned top surface. The top surface of a BE-VCSEL chip may carry metal bumps and bondpads for flip-chip assembly.

"DBR" – distributed Bragg reflector – an optical mirror formed from a stack of alternating semiconductor or dielectric layers with different refractive indices. Each layer is approximately one quarter of the laser wavelength thick, and the partial reflections from each interface add constructively to give high total reflectivity. VCSELs use two DBRs as their top and bottom mirrors.

"EIC" – electronic integrated circuit – an IC that contains electronic circuitry such as laser driver circuits and photodetector interfaces. In MCM 1100, EIC 1120 is the semiconductor chip containing the laser drivers and photodetector 1124.

"GaAs" – gallium arsenide – a III–V compound semiconductor widely used as the substrate material for VCSELs. GaAs is transparent at the emission wavelength of common VCSELs (typically around 850 nm or 940 nm), enabling bottom-emitting operation through the substrate.

"IC" – integrated circuit – a monolithically integrated circuit, i.e., a single semiconductor die, which may be delivered as a bare die or as a packaged circuit. For the purposes of this document, the term integrated circuit also includes packaged circuits that incorporate multiple semiconductor dies, stacked dies, or multiple-die substrates. Such constructions are common in the industry, produced by the same supply chains, and for the average user often indistinguishable from monolithic circuits.

"In-the-field performance monitoring" – a device whose performance may change with age, temperature, supply voltage, and/or other factors may be monitored while it is operational in its final application to determine whether it still functions within the original specifications, or to adjust its drive strength and/or other factors to make it perform as required. For example, a VCSEL's output power may decrease over time. By monitoring its output power, for example with a proximity monitor, its drive strength can be adjusted to increase the output power as needed.

"MCM" – multi-chip module – an assembly that integrates two or more semiconductor chips on a common substrate or interposer.

"MOCVD" – metal-organic chemical vapor deposition – an epitaxial deposition technique used to grow the semiconductor layers of a VCSEL. MOCVD introduces metal-organic precursor gases into a reactor chamber, where they decompose at a heated substrate surface and deposit compound semiconductor layers with precise thickness and doping control.

"Performance metric" – a measurement value indicating a specific aspect of performance of a device, for example the output power, the modulation bandwidth, radio-frequency energy reflection and/or energy transmission, relative intensity noise, power conversion efficiency, temperature stability, threshold current, slope efficiency, wavelength and spectral width, beam divergence, or any other performance parameter known in the art.

"PIC" – photonics integrated circuit – an IC that includes photonic devices such as VCSELs. In MCM 1100, PIC 1130 contains BE-VCSELs 1140 and proximity monitor TE-VCSEL 1150.

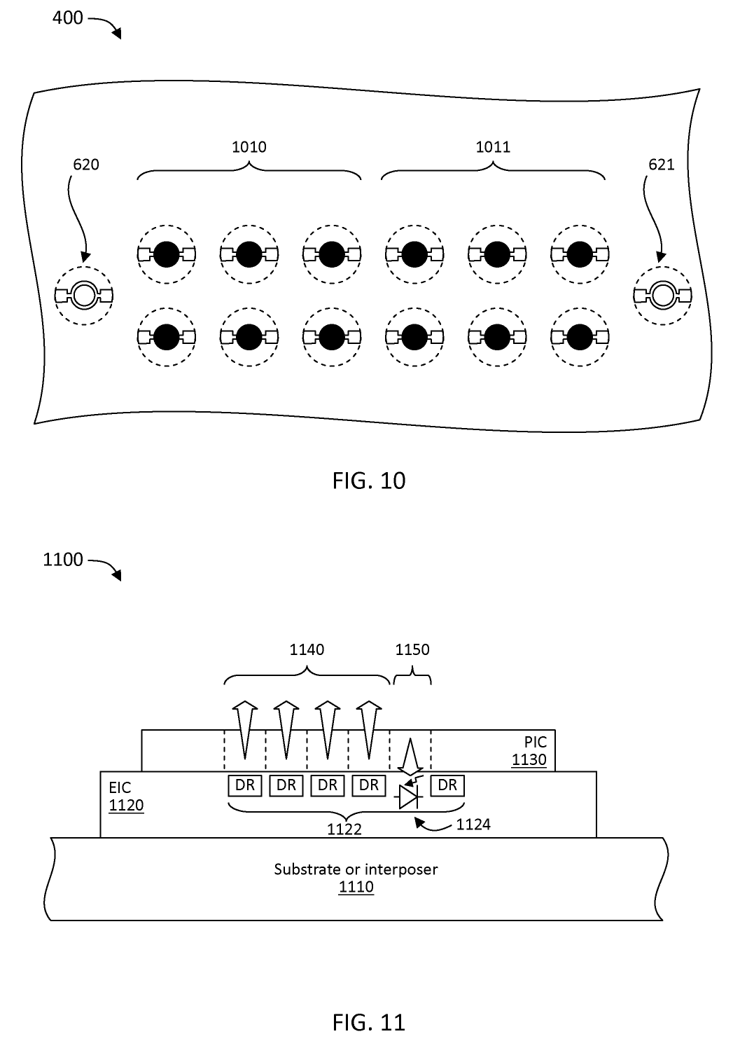

"Proximity monitor" – as used herein, the term "proximity monitor" means a device that, because of proximity to another device and substantially equal conditions of manufacture, can serve as a device that can be tested in lieu of the other device, and whose performance can be trusted as a measure for the performance of the other device. In implementations, an example limit of ten millimeters is proposed. This distance is not necessarily limiting; for example in the case described with reference to FIG. 10 in which interpolation is used, the distance can be greater because the interpolation provides additional accuracy.

"Temperature-based measurement result" – as used herein, a "temperature-based measurement result" is the result of a measurement performed at one or more specific die temperatures or junction temperatures of a die carrying VCSEL devices.

"TE-VCSEL" – top-emitting vertical-cavity surface-emitting laser – a VCSEL in which the laser beam exits through the top mirror, away from the substrate. The laser aperture at the top surface is open, allowing a photodetector placed above the wafer to measure the output power directly.

"VCSEL" – vertical-cavity surface-emitting laser – a semiconductor laser in which the optical cavity is perpendicular to the wafer surface, so that the laser beam is emitted from the wafer’s top or bottom face. VCSELs can be tested while still part of the wafer, before individual chips are singulated.

### IMPLEMENTATIONS

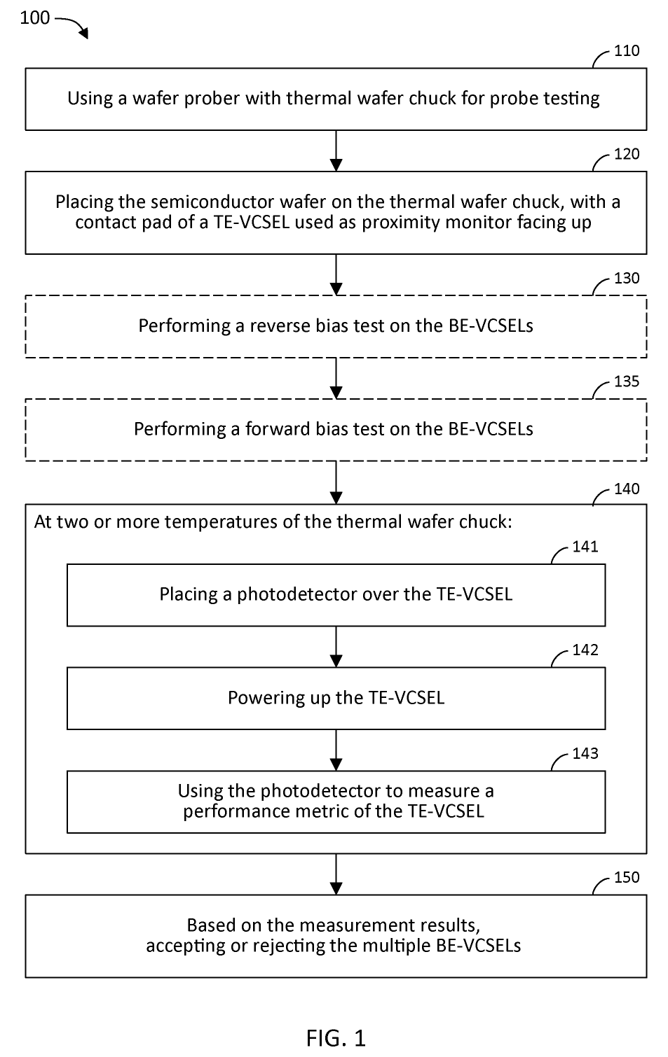

FIG. 1 illustrates an example method 100 of testing a semiconductor wafer 400 with multiple bottom-emitting vertical-cavity surface-emitting lasers (BE-VCSELs) and a proximity monitor top-emitting vertical-cavity surface-emitting laser (TE-VCSEL). The steps in the method are shown as numbered actions in a flow chart.

Action 110 — using a wafer prober with thermal wafer chuck for holding and positioning the semiconductor wafer during testing.

Action 120 — placing the semiconductor wafer on the thermal wafer chuck, with a contact pad of the TE-VCSEL facing up. The semiconductor wafer carries BE-VCSELs that emit laser light downward through the substrate, and a TE-VCSEL that emits upward. When placed face-up on the thermal wafer chuck, the BE-VCSELs emit into the chuck and their optical output is inaccessible for measurement. The TE-VCSEL emits upward, away from the chuck, so a photodetector positioned above the wafer can measure its output power directly.

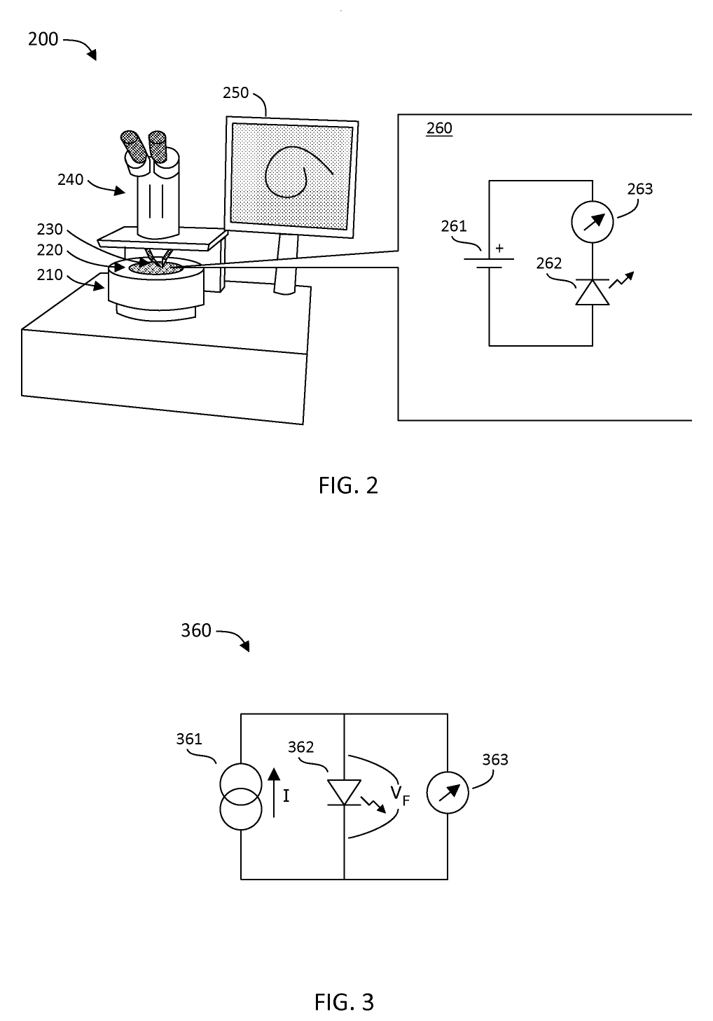

Action 130 — performing a reverse bias test on the multiple BE-VCSELs to reject a defective device, the reverse bias test including applying a positive voltage on a cathode of a BE-VCSEL and measuring a current through the BE-VCSEL. The measurement may be a direct current (DC) measurement and does not need to include optical monitoring of the BE-VCSEL's optical output signal. This step is optional; it is shown with a dashed border in FIG. 1. FIG. 2 illustrates the reverse bias test circuit. A manufacturing defect such as a shorted p-n junction or an anomalous leakage path causes the device to draw significantly more current than a functional device, allowing the defect to be detected electrically without measuring optical output power. A chip with a BE-VCSEL that fails the reverse bias test is marked as defective.

Action 135 — performing a forward bias test on the multiple BE-VCSELs to reject a defective device, the forward bias test including applying a current source to an anode of a BE-VCSEL and measuring a voltage over the BE-VCSEL. The measurement too may be a DC measurement and does not need to include optical monitoring of the BE-VCSEL's optical output signal. This step is also optional (dashed border). FIG. 3 illustrates the forward bias test circuit. A defective device shows a forward voltage outside of a specified range. A chip with a BE-VCSEL that fails the forward bias test is marked as defective.

The optional Action 130 and Action 135 steps may be performed before, after, or in between the temperature-based testing of steps 141–143, to collect baseline electrical measurements of the BE-VCSELs. For example, Action 140 may start with Actions 141 through 143 at room temperature, then proceed with Actions 130 and 135 at room temperature, and follow with Actions 141 through 143 at corner-case temperatures.

FIG. 1 shows steps Actions 141 to 143 as a group that is repeated (Action 140) at two or more temperatures of the thermal wafer chuck. The temperature of the chuck is set and stabilized before each iteration so that the semiconductor wafer with the VCSEL devices is in thermal equilibrium with the thermal wafer chuck.

Action 141 — placing a photodetector over the TE-VCSEL. The photodetector is positioned above the wafer, in the optical path of the upward-emitting TE-VCSEL.

Action 142 — powering up the TE-VCSEL by applying a supply voltage to the TE-VCSEL through the probe tips of the wafer prober.

Action 143 — using the photodetector to measure a performance metric of the TE-VCSEL to obtain a temperature-based measurement result. Because the TE-VCSEL is formed from the same continuous epitaxial layers as the neighboring BE-VCSELs and is located within a few millimeters of them, the performance metric at a given temperature closely tracks the performance of those BE-VCSELs at the same temperature. The performance metric may include the TE-VCSEL's output power, an s-parameter (a radio-frequency (RF) energy reflection or energy transmission parameter), a relative intensity noise (RIN) value, any combination of these, and/or any other performance metric known in the art. The TE-VCSEL emits light from the top surface of the wafer—the same surface from which the probe tips approach. Placing the photodetector above the wafer is straightforward and does not require a transparent chuck, a perforated chuck, or optical access from below.

By repeating Actions 141–143 at two or more temperatures, a temperature-dependent output power profile is built for the TE-VCSEL. This profile shows how the neighboring BE-VCSELs perform across the temperature range they may experience in service.

Action 150 — based at least in part on the temperature-based measurement result, accepting or rejecting the multiple BE-VCSELs. A die or group of dies is accepted if its performance meets specification across all tested temperatures; otherwise it is rejected. The combination of group-level proximity monitoring (actions 140–143) and per-device electrical screening (optional actions 130–135) catches both systematic issues affecting a group of devices and isolated individual defects, without requiring optical access through the back of the wafer.

By using the TE-VCSEL for RF tests (e.g., an s-parameter test or an RIN test), it is possible to keep bondpads for the BE-VCSELs small, which in turn improves the RF performance of the BE-VCSELs.

In some implementations, the semiconductor wafer includes a second TE-VCSEL 621, and method 100 further includes: placing a second photodetector over the second TE-VCSEL; powering up the second TE-VCSEL; using the second photodetector to measure a second performance metric of the second TE-VCSEL to obtain a second temperature-based measurement result; and interpolating between the temperature-based measurement result and the second temperature-based measurement result to obtain a performance estimate for one of the multiple BE-VCSELs.

The performance estimate may be more accurate than could be obtained with just the (first) TE-VCSEL, especially for a BE-VCSEL that may be relatively far from either TE-VCSEL. A more accurate estimate may be beneficial for the yield, as less doubt exists about the performance of a BE-VCSEL that is relatively far away from either of the TE-VCSELs.

In the broadest implementation, method 100 comprises using any top-emitting device formed from the same continuous epitaxial layers as the BE-VCSELs to estimate the performance of the BE-VCSELs at a given temperature. In a narrower implementation, the top-emitting device is a TE-VCSEL within ten millimeters of the BE-VCSELs. In a still narrower implementation, the TE-VCSEL is within five millimeters, and a second TE-VCSEL enables spatial interpolation. In the narrowest implementation, each BE-VCSEL has separate contact pads for active use and probing, less than 35 microns across.

FIG. 2 shows an example of a wafer prober 200 with a wafer chuck 210 on which a semiconductor wafer 220 is tested. The wafer chuck 210 holds the semiconductor wafer 220 and controls its temperature during the test.

The wafer prober 200 may include probe arms 230 that carry probe needles making electrical contact with the contact pads on the semiconductor wafer 220. Alternatively, wafer prober 200 may include a probe ring that carries the probe needles. An optical assembly 240 usually includes a microscope and a camera, and it is mounted above the wafer to assist with alignment and positioning. The wafer prober may include a stepper that automatically positions successive chips, or clusters of chips, under the probe needles. A monitor 250 displays the view from the optical assembly 240.

The inset on the right side of FIG. 2 shows the reverse bias test 260 circuit. A bias source 261 applies a positive voltage to the cathode of BE-VCSEL 262, reverse biasing the junction. A current meter 263 measures the current through the BE-VCSEL 262. In a properly manufactured junction, the BE-VCSEL 262 carries negligible leakage current under reverse bias below the breakdown voltage; the current is recorded at one or more reverse bias voltages and serves as a quality indicator of the semiconductor junction. If the current exceeds a predetermined level, BE-VCSEL 262 is deemed defective, and the chip on which it sits may be rejected.

FIG. 3 illustrates an example of another possible test, forward bias test 360 on a BE-VCSEL 362.

A current source 361 applies a forward current to the anode of BE-VCSEL 362, forward biasing the junction. The forward voltage VF across the BE-VCSEL 362 is recorded at the applied current level. A voltmeter 363 measures the voltage over the BE-VCSEL 362. Devices whose forward voltage falls outside a specified range are rejected as defective.

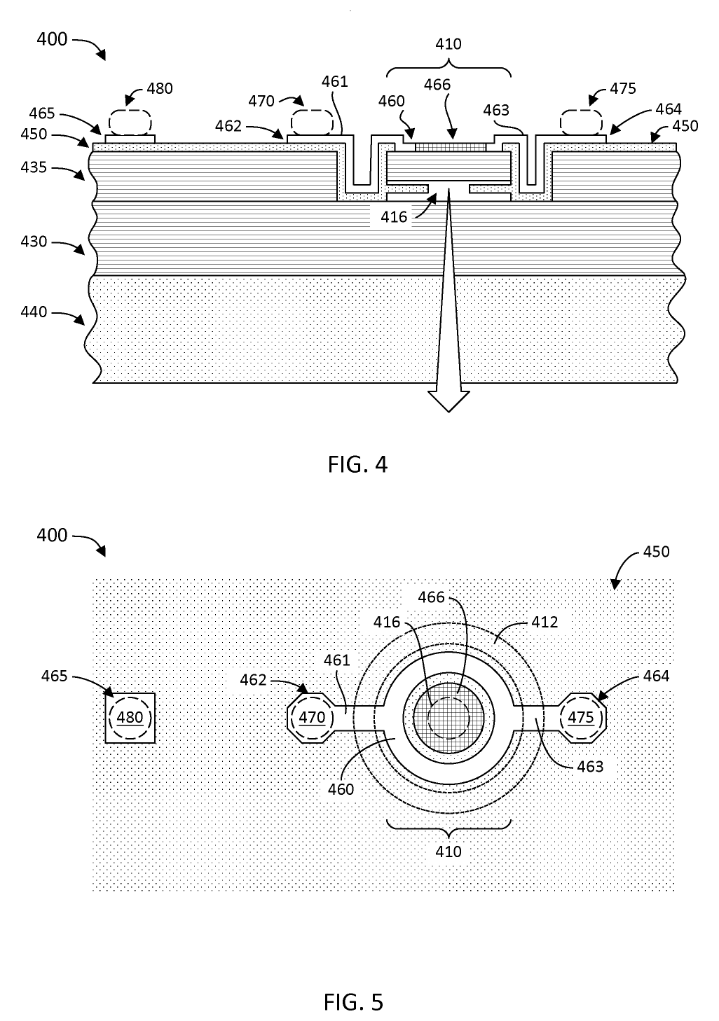

FIG. 4 shows a side view of part of an example semiconductor wafer 400 with a BE-VCSEL 410 that uses much smaller contact pads than conventional VCSELs.

The semiconductor wafer 400 includes a substrate 440 on which a bottom reflector 430 is grown epitaxially. A common substrate material for VCSELs is gallium arsenide (GaAs), which is transparent at the laser wavelength of BE-VCSEL 410, allowing the optical beam to travel downward through substrate 440 and exit from the bottom face of the wafer. The bottom reflector 430 is grown from alternating layers of different refractive index, height, or another characteristic. The choice of materials, the individual layers' height, and the number of layers determines the total amount of reflectivity for a particular wavelength of light. A second stack of alternating epitaxial layers forms a top reflector layer 435. In a BE-VCSEL, the bottom reflector has a lower reflectivity than the top reflector, and in a TE-VCSEL the top reflector has a lower reflectivity than the bottom reflector. To combine BE-VCSELs and TE-VCSELs in one process, differences in reflectivity of the top reflector and bottom reflector can be caused in several ways, for example by locally etching away some of the epitaxial layers in a TE-VCSEL, or by adding a reflector cap 466 in a BE-VCSEL. The epitaxial layers extend continuously across the entire wafer, forming both the BE-VCSELs and the TE-VCSEL from a single, uninterrupted crystal growth.

BE-VCSEL 410 includes a laser aperture 416 formed within the VCSEL mesa, which includes a tunnel diode. Laser aperture 416 is typically created by selective lateral oxidation of an aluminum-rich epitaxial layer, forming an aluminum oxide (also known as ALOX) ring that confines both the driving current and the optical mode to a small active area at the center of the device. This optical and electrical confinement improves lasing efficiency, mode quality, and high-speed performance. A passivation layer 450 covers the top surface, with openings for the metal contacts.

The top contact 460 makes electrical contact with the top of the epitaxial stack. A trace 461 connects the top contact 460 to a contact pad 462 designated for active use (and flip-chip bonding). A separate trace 463 connects the top contact 460 to a contact pad 464 designated for probe testing. Both contact pad 462 and contact pad 464 are smaller than 35 microns (35 µm) across, which is significantly smaller than the combined bondpad in conventional VCSELs. The smaller total metal area reduces parasitic capacitance, enabling higher-speed modulation of the BE-VCSEL.

An optional probe bump 475 is formed on contact pad 464 and absorbs mechanical wear from probe needles during wafer testing, leaving contact pad 462 and its optional active bump 470 undamaged and ready for flip-chip bonding to a receiving substrate. In some implementations, active bump 470 and probe bump 475 may be solder bumps; in other implementations they may be copper pillars (also called Cu pillar bumps), gold bumps, indium bumps, or any other material with suitable electrical and mechanical properties. An optional mechanical stability bump 480 provides mechanical support without an electrical function.

An optional dummy contact plate 465 is a metal feature that provides a bonding or mechanical anchor point without connecting to an active circuit node. A reflector cap 466 marks the optical aperture region on the surface of the TE-VCSEL side of the die. The TE-VCSEL emits light upward (shown by the upward arrow in FIG. 4), while the BE-VCSEL 410 emits downward through the substrate 440 (shown by the downward arrow), as is characteristic of bottom-emitting VCSELs.

Splitting the single conventional bondpad into a contact pad 462 for active use and a separate contact pad 464 for probe testing ensures that probe needle contact during wafer testing cannot damage the flip-chip bonding surface. Because neither pad needs to accommodate both functions, both can be kept well below 35 µm, reducing parasitic capacitance relative to a single large combined pad.

FIG. 5 shows a top view of the part of the semiconductor wafer 400 shown in FIG. 4. BE-VCSEL 410 is surrounded by an etched trench 412, which insulates the actual top reflector from the remainder of top reflector layer 435. Top contact 460 may be shaped as a ring, providing the laser power to BE-VCSEL 410. If shaped as a ring, or similar, inside top contact 460 may be a reflector cap 466 that increases the reflectivity of the top reflector to a value higher than the reflectivity of the bottom reflector. However, in some cases the reflectivity is already higher than the reflectivity of the bottom reflector. In those cases, the TE-VCSEL would be modified to enable the laser beam to emanate from the top. For example, at the site of a TE-VCSEL some of the top reflector layer 435 may be etched away.

The etched trench 412 provides electrical and optical isolation from neighboring devices. A trace 461 connects the top contact 460 to contact pad 462 (for active use), and a trace 463 connects to contact pad 464 (for probe testing). Trace 461 and trace 463 cross etched trench 412 to reach their respective contact pads 462 and 464. The two contact pads are on opposite sides of the device, so that a probe needle contacting contact pad 464 cannot reach contact pad 462. The optional dummy contact plate 465 provides a mechanical anchor point. The bumps (or copper pillars) 470, 475, and 480 are all optional. For example, in case of hybrid bonding neither bumps nor copper pillars are needed.

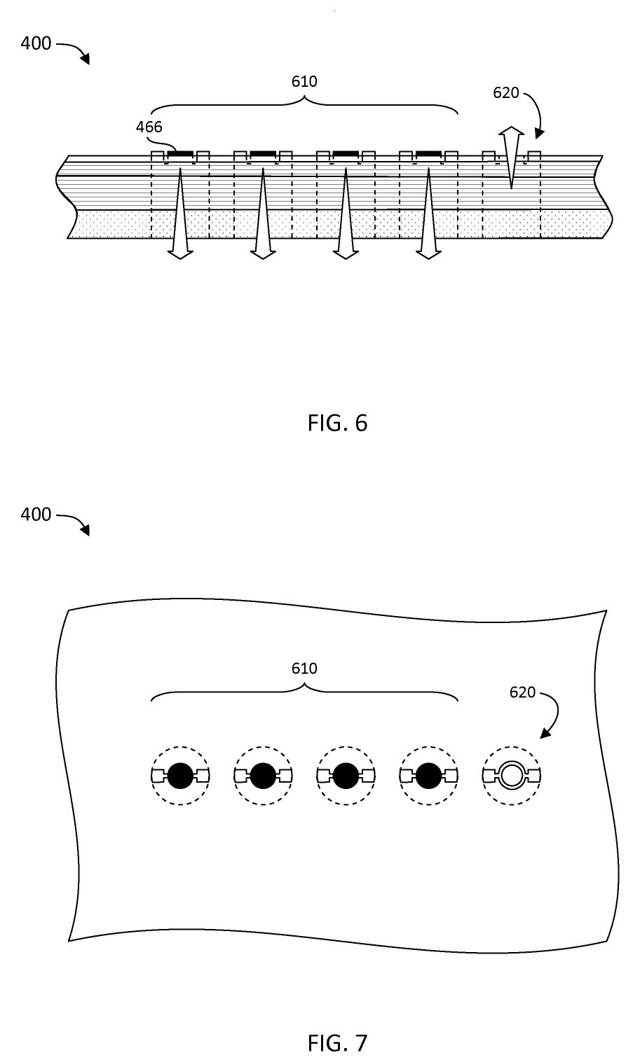

FIG. 6 illustrates a sectional view of a part of an example semiconductor wafer 400 with a row 610 of BE-VCSELs and a TE-VCSEL 620.

The BE-VCSELs in row 610 and the TE-VCSEL 620 are all formed from the same continuous epitaxial layer stacks that run uninterrupted across the semiconductor wafer 400. A reflector cap 466 may be visible on the top surface above each BE-VCSEL. The BE-VCSELs each emit laser light downward through the substrate (shown by downward arrows), while the TE-VCSEL 620 at the end of the row 610 emits laser light upward (shown by the upward arrow). The TE-VCSEL 620 is located within ten millimeters (10 mm) and in some cases even within five millimeters (5 mm) of the BE-VCSELs in the row 610, so that the temperature at the TE-VCSEL 620 during temperature testing substantially matches the temperature at the BE-VCSELs, and the epitaxial material at the TE-VCSEL 620 is representative of the material at the BE-VCSELs. This spatial constraint is what makes the TE-VCSEL 620 a reliable proximity monitor for measuring the performance of the BE-VCSELs during pre-singulation temperature-based production testing of the semiconductor wafer 400.

FIG. 7 illustrates a top view of the part of the semiconductor wafer 400 shown in FIG. 6.

The top view shows row 610 of BE-VCSELs (filled circles) with the TE-VCSEL 620 (open ring) at the end of the row 610. The BE-VCSELs appear as filled circles because they emit downward through the substrate. The TE-VCSEL 620 appears as an open ring through which it emits upward.

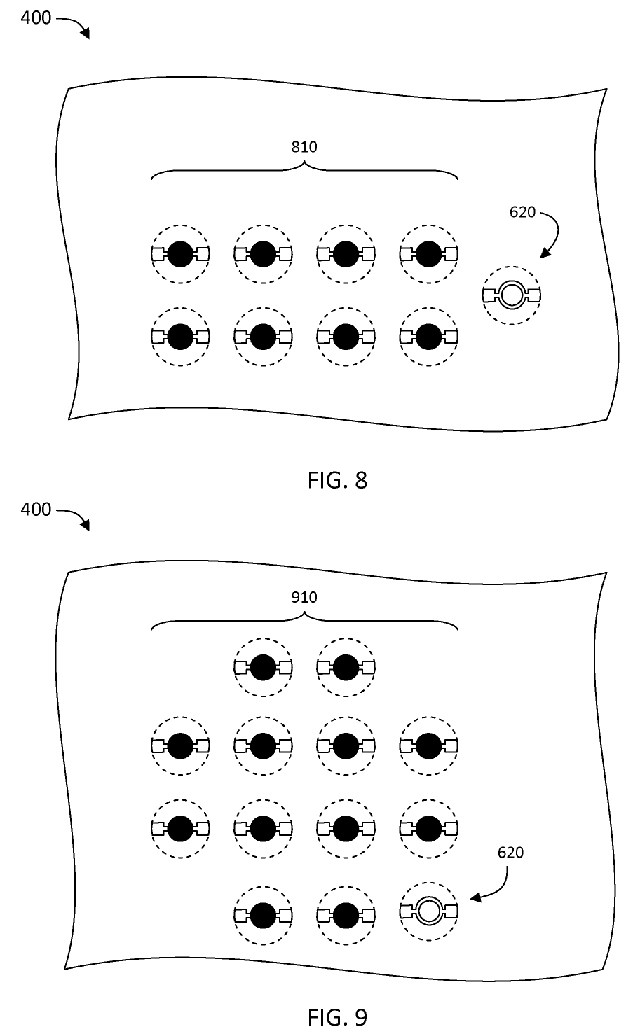

FIG. 8 illustrates a top view of an arrangement of BE-VCSELs in a two-dimensional array 810. The two-dimensional array may have a rectangular shape, as depicted, a polygonal shape, a round shape, a regular shape, as depicted, an irregular shape, or any other shape. In this example, the two-dimensional array 810 is a rectangular array of BE-VCSELs. Although in this example the array has a consistent arrangement of rows and columns, in some other arrangements not all rows may have the same number of VCSELs, and not all columns may have the same number of VCSELs. The TE-VCSEL 620 is placed at a corner or edge of the two-dimensional array 810, within 10 mm or even 5 mm of the BE-VCSELs in the array. The semiconductor wafer 400 may carry many such arrays; each array may be served by its own TE-VCSEL during wafer testing. For larger two-dimensional arrays whose physical extent exceeds the ten-millimeter proximity range, multiple TE-VCSELs may be used for proximity monitoring, as illustrated in FIG. 10.

FIG. 9 illustrates a top view of an example octagonal arrangement of BE-VCSELs 910.

The octagonal arrangement of BE-VCSELs 910 groups multiple BE-VCSELs in a compact footprint with an octagonal outline. The TE-VCSEL 620 is positioned adjacent to the octagonal arrangement of BE-VCSELs 910, within 10 mm or even 5 mm of the BE-VCSELs in the arrangement. By keeping the TE-VCSEL 620 within this proximity, its measured optical output power remains a reliable proxy for the performance of the surrounding BE-VCSELs across all tested temperatures. For larger octagonal or hexagonal arrangements whose extent exceeds the proximity range, multiple TE-VCSELs may be used.

FIG. 10 illustrates an example semiconductor wafer 400 in which the TE-VCSEL 620 is located within ten millimeters (10 mm) from the first part 1010 of the BE-VCSELs, and a second TE-VCSEL 621 is located within ten millimeters from a second part 1011 of the BE-VCSELs.

The TE-VCSEL 620 serves as the proximity monitor for the BE-VCSELs in the first part 1010, and the second TE-VCSEL 621 serves as the proximity monitor for the BE-VCSELs in the second part 1011. Each TE-VCSEL is within 10 mm of the BE-VCSELs it monitors. The second part 1011 may at least partially overlap with the first part 1010, meaning some BE-VCSELs may belong to both parts. This arrangement shows that a single die may include multiple groups of BE-VCSELs each served by its own TE-VCSEL, enabling independent temperature characterization of each group on the same wafer.

The use of two or more proximity monitor TE-VCSELs enables spatial interpolation when estimating the output power levels of the BE-VCSELs across the array. For example, if the output power measured from TE-VCSEL 620 differs from that measured from TE-VCSEL 621, the expected output power of BE-VCSELs at intermediate positions can be estimated by interpolating between the two measured values. This increases the accuracy of the performance estimation and can extend effective monitoring coverage even beyond ten millimeters for suitably spaced TE-VCSEL pairs.

FIG. 11 illustrates a part of an example multi-chip module (MCM 1100) configured for in-the-field performance monitoring.

The MCM 1100 may include a substrate or interposer 1110 that provides a mounting surface and electrical interconnections. An electronic integrated circuit (EIC 1120) is mounted on the substrate or interposer 1110. The EIC 1120 includes two or more laser driver circuits 1122 and a photodetector 1124. A photonics integrated circuit (PIC 1130) is flip-chip mounted on the EIC 1120.

The PIC 1130 includes one or more BE-VCSELs 1140 and a TE-VCSEL 1150 serving as a proximity monitor. A first of the two or more laser driver circuits 1122 is electrically coupled with a BE-VCSEL 1140 to drive its optical output. A second of the two or more laser driver circuits 1122 is electrically coupled with the TE-VCSEL 1150 to drive its optical output.

Because the PIC 1130 is flip-chip mounted on the EIC 1120, the TE-VCSEL 1150 emits downward, directly toward the EIC 1120, where the photodetector 1124 receives the emitted light. Thus, photodetector 1124 is optically coupled with the TE-VCSEL 1150 and is configured to measure an output power of the TE-VCSEL 1150. The EIC 1120 uses the output signal of the photodetector 1124 for in-the-field performance monitoring of the BE-VCSELs 1140. The in-the-field performance monitoring function of EIC 1120 is performed by circuitry within EIC 1120 that receives the output signal of photodetector 1124, processes the output signal to determine the optical output power of TE-VCSEL 1150, and uses that determination to monitor and optionally adjust the drive current supplied by the two or more laser driver circuits 1122. In some implementation, the determination is made by circuitry outside of EIC 1120, for example by another IC in the same package, or by an external processor or microcontroller. These structural correspondences are provided for compliance with 35 U.S.C. Section 112 and are not intended to limit the scope of the claims beyond their plain meaning.

In some implementations, the monitoring is continuous. In some implementations, the monitoring occurs at regular time intervals. In some implementations, the EIC 1120 uses the monitoring result to control an optical output power level of one or more of the BE-VCSELs 1140, for example by adjusting the drive current supplied by one of the two or more laser driver circuits 1122.

In the claims section, Claim 1 is directed to a method of wafer-level production testing. Claim 7 is directed to the structural configuration of the semiconductor wafer itself, including the specific combination of BE-VCSELs and TE-VCSEL formed from continuous epitaxial layers. Claim 12 is directed to the multi-chip module assembly that applies the proximity monitoring concept for in-the-field use after singulation and assembly. Each claim set is independently intended to capture a distinct aspect of the inventive concept.

### PARTICULAR IMPLEMENTATIONS

Described implementations of the subject matter can include one or more features, alone or in combination, as described in the following clauses.

Clause 1. A method (100) of testing a semiconductor wafer (400) including multiple bottom-emitting vertical-cavity surface-emitting lasers (BE-VCSELs) (410, 610, 810, 910) and a top-emitting vertical-cavity surface-emitting laser (TE-VCSEL) (620) serving as a proximity monitor, the method comprising:

(110) using a wafer prober with a thermal wafer chuck for holding and positioning the semiconductor wafer during testing;

(120) placing the semiconductor wafer on the thermal wafer chuck, with a contact pad of the TE-VCSEL facing up;

(140) at two or more temperatures of the thermal wafer chuck:

(141) placing a photodetector over the TE-VCSEL;

(142) powering up the TE-VCSEL; and

(143) using the photodetector to measure a performance metric of the TE-VCSEL to obtain a temperature-based measurement result; and

(150) based at least in part on the temperature-based measurement result, accepting or rejecting the multiple BE-VCSELs.

Clause 2. The method of clause 1, wherein the performance metric includes at least one of:

an output power,

a radio-frequency (RF) energy reflection and/or energy transmission parameter (s-parameter), or

a relative intensity noise (RIN) value.

Clause 3. The method of any of clauses 1 or 2, further comprising (130) performing a reverse bias test (260) on the multiple BE-VCSELs to reject a defective device, the reverse bias test including applying a positive voltage to a cathode of a BE-VCSEL (262) and measuring a current through the BE-VCSEL.

Clause 4. The method of any of clauses 1 to 3, further comprising (135) performing a forward bias test (360) on the multiple BE-VCSELs to reject a defective device, the forward bias test including applying a current source to an anode of a BE-VCSEL (362) and measuring a voltage over the BE-VCSEL.

Clause 5. The method of any of clauses 1 to 4, wherein the semiconductor wafer includes a second TE-VCSEL (621) and the method further comprises:

placing a second photodetector over the second TE-VCSEL;

powering up the second TE-VCSEL;

using the second photodetector to measure a second performance metric of the second TE-VCSEL to obtain a second temperature-based measurement result; and

interpolating between the temperature-based measurement result and the second temperature-based measurement result to obtain a performance estimate for one of the multiple BE-VCSELs.

Clause 6. The method of any of clauses 1 to 5, wherein a BE-VCSEL (410) has separate contact pads for active use (462) and probe testing (464), and a size of the contact pads, measured across, is less than 35 microns.

Clause 7. A semiconductor wafer (400, 1130), comprising:

multiple bottom-emitting vertical-cavity surface-emitting lasers (BE-VCSELs) (610, 810, 910, 1140); and

a top-emitting vertical-cavity surface-emitting laser (TE-VCSEL) (620, 1150) serving as a proximity monitor for measuring performance of the BE-VCSELs during pre-singulation temperature-based production testing of the semiconductor wafer;

wherein:

the BE-VCSELs and the TE-VCSEL are formed from the same continuous epitaxial layers on the semiconductor wafer;

at least a first part of the BE-VCSELs is within a range of ten millimeters (10 mm) from each other; and

the BE-VCSELs have separate contact pads (462, 464) for active use and probe testing, and a size of the contact pads, measured across, is less than 35 microns.

Clause 8. The semiconductor wafer of clause 7, wherein the TE-VCSEL is located within ten millimeters (10 mm) of the BE-VCSELs.

Clause 9. The semiconductor wafer of any of clauses 7 or 8, wherein the BE-VCSELs are arranged in a row of devices, and the TE-VCSEL is located at an end of the row of devices.

Clause 10. The semiconductor wafer of any of clauses 7 or 8, wherein the BE-VCSELs are arranged in a two-dimensional array, and the TE-VCSEL is located at an edge or a corner of the two-dimensional array.

Clause 11. The semiconductor wafer of any of clauses 7 to 10, wherein the TE-VCSEL is located within ten millimeters (10 mm) from the first part (1010) of the BE-VCSELs, and a second TE-VCSEL (621) is located within ten millimeters (10 mm) from a second part (1011) of the BE-VCSELs, wherein the second part of the BE-VCSELs at least partially overlaps with the first part of the BE-VCSELs.

Clause 12. A multi-chip module (MCM) (1100), comprising:

an electronic integrated circuit (EIC) (1120) including two or more laser driver circuits (1122) and a photodetector (1124); and

a photonics integrated circuit (PIC) (1130) including one or more bottom-emitting vertical-cavity surface-emitting lasers (BE-VCSELs) (1140) and a top-emitting vertical-cavity surface-emitting laser (TE-VCSEL) (1150) serving as a proximity monitor;

wherein:

the PIC is flip-chip mounted on the EIC;

a first of the two or more laser driver circuits is electrically coupled with the one or more BE-VCSELs;

a second of the two or more laser driver circuits is electrically coupled with the TE-VCSEL;

the photodetector is optically coupled with the TE-VCSEL and configured to measure an output power of the TE-VCSEL; and

the EIC is configured to use an output signal of the photodetector for in-the-field performance monitoring.

Clause 13. The MCM of clause 12, wherein the in-the-field performance monitoring is continuous.

Clause 14. The MCM of clause 12, wherein the in-the-field performance monitoring is at regular times.

Clause 15. The MCM of any of clauses 12 to 14, wherein the EIC uses the in-the-field performance monitoring to control an optical output power level of one of the one or more BE-VCSELs.

Clause 16. The MCM of any of clauses 12 to 15, wherein the BE-VCSELs have separate contact pads (462, 464) for active use and probe testing, and a size of the contact pads, measured across, is less than 35 microns.

### CONSIDERATIONS

We describe various implementations of a vertical-cavity surface-emitting laser.

The technology disclosed can be practiced as an apparatus, method, or article of manufacture. One or more features of an implementation can be combined with the base implementation. Implementations that are not mutually exclusive are taught to be combinable. One or more features of an implementation can be combined with other implementations. This disclosure periodically reminds the user of these options. Omission from some implementations of recitations that repeat these options should not be taken as limiting the combinations taught in the preceding sections—these recitations are hereby incorporated forward by reference into each of the implementations described herein.

Although the description has been described with respect to specific implementations thereof, these specific implementations are merely illustrative, and not restrictive. The description may reference specific structural implementations and methods and does not intend to limit the technology to the specifically disclosed implementations and methods. The technology may be practiced using other features, elements, methods and implementations. Implementations are described to illustrate the present technology, not to limit its scope, which is defined by the claims. Those of ordinary skill in the art recognize a variety of equivalent variations on the description above.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Different semiconductor materials can be employed, such as gallium arsenide (GaAs), aluminum gallium arsenide (AlGaAs), silicon, germanium, SiGe, InP, GaN, SiC, diamond, graphene, etc.

It will also be appreciated that one or more of the elements depicted in the drawings/figures can also be implemented in a more separated or integrated manner, or even removed or rendered as inoperable in certain cases, as is useful in accordance with a particular application.

Thus, while specific implementations have been described herein, latitudes of modification, various changes, and substitutions are intended in the foregoing disclosures, and it will be appreciated that in some instances some features of specific implementations will be employed without a corresponding use of other features without departing from the scope and spirit as set forth. Therefore, many modifications may be made to adapt a particular situation or material to the essential scope and spirit.

What is claimed is:

1. A method of testing a semiconductor wafer including multiple bottom-emitting vertical-cavity surface-emitting lasers (BE-VCSELs) and a top-emitting vertical-cavity surface-emitting laser (TE-VCSEL) serving as a proximity monitor, the method comprising: using a wafer prober with a thermal wafer chuck for holding and positioning the semiconductor wafer during testing; placing the semiconductor wafer on the thermal wafer chuck, with a contact pad of the TE-VCSEL facing up;at two or more temperatures of the thermal wafer chuck: placing a photodetector over the TE-VCSEL; powering up the TE-VCSEL; and using the photodetector to measure a performance metric of the TE-VCSEL to obtain a temperature-based measurement result; and based at least in part on the temperature-based measurement result, accepting or rejecting the multiple BE-VCSELs.

2. The method of claim 1, wherein the performance metric includes at least one of: an output power, a radio-frequency (RF) energy reflection and/or energy transmission parameter (s-parameter), or a relative intensity noise (RIN) value.

3. The method of claim 1, further comprising performing a reverse bias test on the multiple BE-VCSELs to reject a defective device, the reverse bias test including applying a positive voltage to a cathode of a BE-VCSEL and measuring a current through the BE-VCSEL.

4. The method of claim 1, further comprising performing a forward bias test on the multiple BE-VCSELs to reject a defective device, the forward bias test including applying a current source to an anode of a BE-VCSEL and measuring a voltage over the BE-VCSEL.

5. The method of claim 1, wherein the semiconductor wafer includes a second TE-VCSEL and the method further comprises: placing a second photodetector over the second TE-VCSEL; powering up the second TE-VCSEL; using the second photodetector to measure a second performance metric of the second TE-VCSEL to obtain a second temperature-based measurement result; and interpolating between the temperature-based measurement result and the second temperature-based measurement result to obtain a performance estimate for one of the multiple BE-VCSELs.

6. The method of claim 1, wherein a BE-VCSEL has separate contact pads for active use and probe testing, and a size of the contact pads, measured across, is less than 35 microns.

7. A semiconductor wafer, comprising: multiple bottom-emitting vertical-cavity surface-emitting lasers (BE-VCSELs); and a top-emitting vertical-cavity surface-emitting laser (TE-VCSEL) serving as a proximity monitor for measuring performance of the BE-VCSELs during pre-singulation temperature-based production testing of the semiconductor wafer; wherein: the BE-VCSELs and the TE-VCSEL are formed from the same continuous epitaxial layers on the semiconductor wafer; at least a first part of the BE-VCSELs is within a range of ten millimeters (10 mm) from each other; and the BE-VCSELs have separate contact pads for active use and probe testing, and a size of the contact pads, measured across, is less than 35 microns.

8. The semiconductor wafer of claim 7, wherein the TE-VCSEL is located within ten millimeters (10 mm) of the BE-VCSELs.

9. The semiconductor wafer of claim 7, wherein the BE-VCSELs are arranged in a row of devices, and the TE-VCSEL is located at an end of the row of devices.

10. The semiconductor wafer of claim 7, wherein the BE-VCSELs are arranged in a two-dimensional array, and the TE-VCSEL is located at an edge or a corner of the two-dimensional array.

11. The semiconductor wafer of claim 7, wherein the TE-VCSEL is located within ten millimeters (10 mm) from the first part of the BE-VCSELs, and a second TE-VCSEL is located within ten millimeters (10 mm) from a second part of the BE-VCSELs, wherein the second part of the BE-VCSELs at least partially overlaps with the first part of the BE-VCSELs.

12. A multi-chip module (MCM), comprising: an electronic integrated circuit (EIC) including two or more laser driver circuits and a photodetector; and a photonics integrated circuit (PIC) including one or more bottom-emitting vertical-cavity surface-emitting lasers (BE-VCSELs) and a top-emitting vertical-cavity surface-emitting laser (TE-VCSEL) serving as a proximity monitor; wherein: the PIC is flip-chip mounted on the EIC; a first of the two or more laser driver circuits is electrically coupled with the one or more BE-VCSELs; a second of the two or more laser driver circuits is electrically coupled with the TE-VCSEL; the photodetector is optically coupled with the TE-VCSEL and configured to measure an output power of the TE-VCSEL; and the EIC is configured to use an output signal of the photodetector for in-the-field performance monitoring.

13. The MCM of claim 12, wherein the in-the-field performance monitoring is continuous.

14. The MCM of claim 12, wherein the in-the-field performance monitoring is at regular times.

15. The MCM of claim 12, wherein the EIC uses the in-the-field performance monitoring to control an optical output power level of one of the one or more BE-VCSELs.

16. The MCM of claim 12, wherein the BE-VCSELs have separate contact pads for active use and probe testing, and a size of the contact pads, measured across, is less than 35 microns.

17. The MCM of claim 12, wherein the TE-VCSEL is located within ten millimeters (10 mm) from the one or more BE-VCSELs.
